(19) United States
(12) Patent Application Publication
(10) Pub. No.: US 2008/0191808 A9
(43) Pub. Date: Aug. 14, 2008

(54) Layout for a time base

(76) Inventor: David Ruffieux, Lugnorre (CH)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/556,909

(22) PCT Filed: May 12, 2004
(86) PCT No.: PCT/CH04/00288

§ 371 Date: Nov. 15, 2005

(30) Foreign Application Priority Data
May 15, 2003 (FR) 0305834

(51) Int. Cl. H03L 7/00

(52) U.S. Cl. 331/16

(57) ABSTRACT

Time base including two oscillators, one of which has a lower frequency than the other, the latter being intermittently set to standby mode, generating according to the same intermittency a first stable time reference (REF) by difference between the frequencies of the two oscillators, a second permanent time reference (RTC) being obtained by division of the frequency of the oscillator having the lowest frequency and the division factor being dependent on the pulses counted for the first oscillator (OSC1) during a time interval determined by the first stable time reference (REF).

The invention relates to layout, in particular for a timepiece time base, intended to generate a time reference, and to a method of generating a time reference.

In the field of timepieces, the problem arises of the accuracy of the time bases present in the timepieces and, more particularly for chronometers, that of the correction of the signal output by a resonator in order to compensate the frequency drift of this signal due to the temperature.

Most known time bases include a tuning fork type 32 kHz resonator, the cut of which is chosen to cancel the first order thermal coefficient of the thermal characteristic. This gives a timekeeper with a square-law thermal characteristic giving a drift of −20 ppb/°C². However, this drift is still too high and does not permit a time base accuracy such that a timepiece equipped with it can achieve the distinction of chronometer, for example, in accordance with the standards of the Contrôle Officiel Suisse des Chronomètres (Swiss Official Chronometer Testing Institute COSC).

Various solutions for reducing the effect of such a drift have been devised by clock makers. A first solution involves implementing an electronic compensation by inhibition tuning following a temperature measurement. This solution, however, requires the availability of an appropriate temperature measurement and the implementation of an initial calibration step. Another solution is disclosed in the document entitled “A microprocessor-based analog wristwatch chip with 3-seconds/year accuracy”, by D. Lanfranchi, E. Dijkstra and D. Aebischer, CSEM Centre Suisse d'Electronique et de Microtechnique (Swiss Centre for Electronics and Microtechnology), ISSCC 1994. This document discloses a solution assuming the use of a ZT-cut quartz resonator with zero first and second order thermal coefficients. In this case, a resonator working at a high frequency, around 2 MHz, is used as a time reference for determining whether there is frequency drift on another, lower precision, quartz resonator, the frequency of which is around 32 kHz. This solution, however, entails adding a high frequency ZT quartz resonator, which results in a high consumption for the system. To overcome this high consumption problem, the ZT quartz is used in combination with a 32 kHz quartz, which has lower precision but which by regularly switching the oscillator using the ZT quartz to standby mode, can be used to achieve a very low average consumption. Depending on the thermal inertia of the timepiece, the higher precision time reference is reactivated periodically, for a brief moment, to resynchronize the two time bases. However, this solution requires the availability of a high precision resonator with a frequency that is highly stable temperature-wise. Also, the addition of a ZT-type quartz resonator adds to the production cost and size, both of which are undesirable.

The document entitled “Résonateurs intégréds et base de temps incorporant de tels résonateurs” (“Integrated resonators and time bases incorporating such resonators”) which is the subject of a French patent application filed by the applicant on the same day as this application, discloses a time base including two resonators integrated in a silicon substrate, using different resonance modes and oscillating at different frequencies. These resonators each present a very high frequency drift due to the temperature. It is observed that, in the conditions of implementation of these resonators as disclosed, the difference between the signals output by the two resonators can be used to obtain a very accurate time reference, the thermal drift of which is very low. Cancellation of the first order thermal coefficient is obtained by difference between the frequencies of these two resonators. The reduction of the second order thermal coefficient is achieved by an appropriate orientation of the two resonators in their substrate. It is then possible, based on such resonators, to construct a time base that is stable temperature-wise and accurate enough to be considered for application to chronometers. However, as indicated in the above-mentioned patent application, the frequencies of such resonators are high, which again leads to an excessively high time base consumption for portable applications, such as wristwatches.

The object of the invention is therefore to overcome the above-mentioned drawbacks and in particular to provide a layout based on resonators, the frequency of which is not necessarily stable temperature-wise, such as silicon resonators, and which can be used to obtain an accurate and low consumption time base, regardless of the surrounding thermal conditions.

The subject of the invention is therefore a layout, in particular for time bases, the output signal of which is intended to form a time reference, including:
a first oscillator including a silicon resonator of frequency F₁,
a second oscillator including a silicon resonator, the frequency F₂ of which is different from that of the first oscillator,
means for generating, by difference between the signal output by the first oscillator and the signal output by the second oscillator, a first temperature-stable time reference,
means for determining the frequency drift due to the temperature of the signal output by the first oscillator by comparing the signal output by the first oscillator with the first temperature-stable time reference,
programmable correction means which, according to the value of said drift, divide the frequency of the signal output by the first oscillator and generate said output signal forming a second temperature-stable time reference.

The layout according to the invention can also have the following characteristics:
the layout includes means for counting, during a counting phase and over a predetermined number of cycles of the first time reference, the number of pulses generated by the first oscillator, and
the layout includes means for determining said frequency drift and controlling said programmable correction means, according to said number of pulses counted and said number of cycles of the first time reference during which counting was enabled,
the layout includes means of selecting standby mode for intermittently setting the second oscillator to standby mode, and said counting phase runs during a phase of activity of the second oscillator,
said means of selecting standby mode include means for varying the time interval between two successive reactivations, according to the accuracy required for the second time reference and/or to the number of pulses counted for the first oscillator in at least one of the preceding counting phases,
the layout includes means for generating temperature information from the number of pulses generated by the first oscillator in the counting phase,
the layout includes means for storing calibration information concerning the first temperature-stable time reference,
the correction means include a programmable frequency divider having a range of division factors with which to compensate the frequency drifts of the first oscillator due to the temperature and/or the absolute accuracy of the first oscillator,
the second oscillator includes a silcon resonator, the first order thermal coefficient of which is in a ratio λ.F₁/F₂ with the first order thermal coefficient of the first oscillator, and a frequency divider dividing the frequency F₂ of the signal output by this resonator by a factor λ and generating the output signal of the second oscillator.

Another subject of the invention is a method of generating a signal intended to form a time reference including the following steps:
generation of a first frequency by a first oscillator including a silicon resonator,
generation of a second frequency, different from the first frequency by a second oscillator including a silicon resonator, the first order thermal coefficient of the first oscillator being roughly equal to the first order thermal coefficient of the second oscillator multiplied by the ratio F₂/λ.F₁,
generation of a first temperature-stable time reference by difference between the signal output by the first oscillator and the signal output by the second oscillator,
determination, by comparison of the signal output by the first oscillator with the first time reference, of the frequency drift due to the temperature of the signal output by the first oscillator,
correction, according to the value of said drift, of the frequency of the signal output by the first oscillator to generate said output signal forming a second time reference.

The invention exploits these characteristics in order to generate, in a simple manner, using silicon resonators, a time reference that is accurate enough to satisfy the requirements of the COSC. In particular, the invention does not require the use of high precision resonators, or resonators that are very stable temperature-wise such as ZT quartz resonators, which can be costly or increase the size and the manufacturing complexity of the time base. Furthermore, a silicon resonator-based implementation makes it possible to consider the use of the device according to the invention in various applications, in particular those already using silicon-based integrated circuits such as, for example, handheld computers, personal digital assistants and other small-size electronic devices.

Other characteristics and advantages of this invention will become apparent from the description that follows, given purely as an example, and with reference to the appended figures in which:

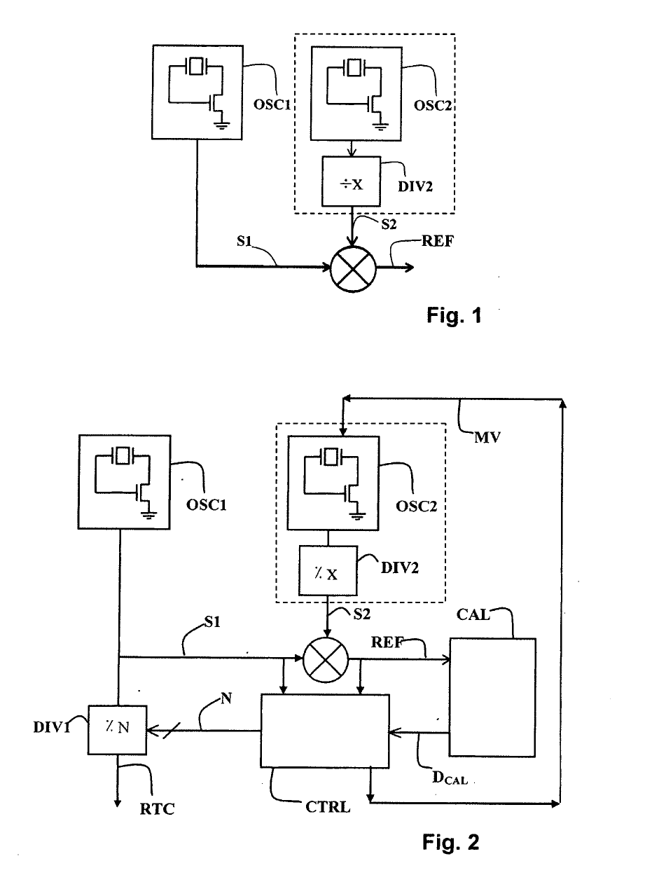

FIG. 1 is a schematic diagram of a time base as disclosed in the above-mentioned parallel application,

FIG. 2 is a schematic diagram of a time base according to the invention,

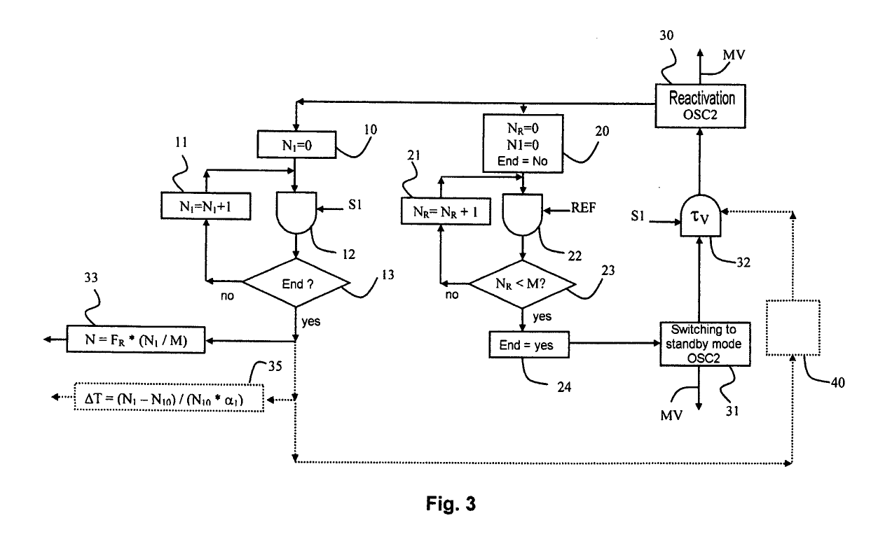

FIG. 3 is a flow diagram describing the operation of the control block CTRL included in the layout according to the invention.

FIG. 1 represents a schematic diagram of a time base using the frequency difference of the signals from two oscillators, each including a silicon resonator. In this figure, the first oscillator OSC1 operates at a lower frequency than the oscillator OSC2. At the output of the second oscillator, there is a frequency divider DIV2, associated with the second oscillator OSC2 and performing a frequency division by an integer number λ. The frequency difference between the signal S1 from the first oscillator OSC1 and the signal S2 from the second oscillator OSC2, after frequency division by a factor λ, forms a time reference REF, the frequency of which is stable, if the ratio between the frequencies is the inverse of the ratio of their first order thermal coefficient.

As disclosed in the above-mentioned parallel application, if the two oscillators OSC1, OSC2, are chosen to satisfy the above condition, a cancellation of the first order thermal coefficient for the time reference REF is obtained, and therefore a stable frequency difference is obtained, even though each of the two oscillators presents a wide thermal drift.

In practice, if the frequency F₁ of the first oscillator OSC1 is, as a first approximation, such that:
F₁(ΔT)=F₁₀*(1+α₁*ΔT)

ΔT being a temperature variation, α₁ being the first order thermal coefficient of the oscillator OSC1 and F₁₀ being its natural frequency,

and if the frequency F₂ of the second oscillator OSC2 is, as a first approximation, such that:
F₂(ΔT)=F₂₀*(1+α₂*ΔT)

α₂ being the first order thermal coefficient of the oscillator OSC2 and F₂₀ being its natural frequency, and also, the following condition is satisfied:
λ*α₁*F₁₀=α₂*F₂₀

then, after division of the frequency of the second oscillator OSC2 by a factor λ, a frequency F′₂ is obtained, such that:
F′₂(ΔT)=F₂(ΔT)/λ=(F₂₀/λ)*(1+α₂*ΔT)=(F₁₀*α₁/α₂)(1+α₂*ΔT).

Furthermore, by difference between F′₂ and F₁, a frequency F_{R} is obtained such that:
F_{R}(ΔT)=F′₂(ΔT)−F₁(ΔT)=F₁₀*(α1−α2)/α2

that is, by disregarding the higher order thermal coefficients, a temperature-independent frequency, which is that of the time reference REF. As stated previously, the above-mentioned patent application also provides means for cancelling, or greatly reducing, the second order thermal coefficient of the frequency difference F_{R}.

FIG. 2 diagrammatically represents a layout, in particular for time bases, using the principle which has just been described. The layout includes a first oscillator OSC1 which operates at a lower frequency than a second oscillator OSC2. Programmable correction means act on the output of the first oscillator OSC1, performing a programmable division of the frequency of the signal S1 output by the first oscillator OSC1 and thus generating the time base output time reference RTC. The programmable correction means are implemented, according to the example of FIG. 2, by a programmable divider performing a frequency division by a factor N on the signal S1 output by the first oscillator.

A second divider DIV2 acts on the output of the second oscillator OSC2, performing a frequency division by an integer number λ and generating a signal S2, on the basis of which the difference with the output S1 of the first oscillator OSC1 forms a first time reference REF. As explained previously, the oscillators are chosen such that at least the first order thermal coefficient of the signal REF is zero. In this way, the frequency of the first time reference REF is stable temperature-wise.

The time base according to the invention also includes a calibration block CAL used in an initial calibration phase and which, in normal operation outside this calibration phase, is used to store data derived from the calibration.

This calibration block CAL is linked to a control block CTRL, the function of which is to control the programmable divider DIV1 linked to the first, low consumption oscillator OSC1. For this, this control block uses the signal S1 generated by the first oscillator OSC1, the stable reference signal REF and the data D_{CAL} stored in the calibration block and derived from the calibration phase. Also, this control block CTRL generates control signals MV for switching to standby mode or, conversely, reactivating the oscillator OSC2, with the oscillator OSC1 running permanently.

The theory of operation of this layout and the various embodiments are described in greater detail below.

The calibration block CAL stores in memory a value of the stable reference frequency REF. This value is obtained in an initial calibration phase during which this stable reference is compared with a very accurate external reference. This can be done, for example, by measuring the time needed relative to this external reference to count a given number of pulses of the stable reference REF, number equal to 10⁶, for example, to obtain an accuracy of one ppm (10⁻⁶). The value of the stable reference frequency REF is then obtained by calculating the ratio between the number of pulses counted and the calibration time measured using the external reference. Thus, if the calibration time is 1.872 s, the stable reference frequency will be 10⁶/1.872=0.534 MHz. Depending on the required measurement accuracy, the number of pulses may be higher, but the calibration time will be proportionally greater.

The value of the stable reference frequency REF obtained by calibration is stored in the calibration block CAL, for example with an accuracy of around one ppm. The initial calibration can be done at ambient temperature without adversely affecting the accuracy of the measurement, because the temperature drift of the stable reference REF is very low. The value of this reference frequency is stored in a non-volatile manner in the calibration block CAL, so as to be available in normal operation outside the time base calibration phase.

The control block CTRL uses this calibration information to generate, from the output signal S1 of the first oscillator OSC1 and the stable reference signal REF, a control signal controlling said correction means. In the example of FIG. 2, this control signal is used to adjust the division factor N of the first programmable divider DIV1 acting on the output of the first oscillator OSC1.

The way this control signal is determined is described by the flow diagram in FIG. 3. In this flow diagram, there is a counting phase during which, in parallel, the pulses of the signal S1 output by the first oscillator OSC1 and the pulses of the stable reference REF are counted.

The determination process begins when, in the step 30, the second oscillator OSC2 is reactivated by means of a reactivation signal MV generated by the control block CTRL. The stable reference REF is then available for the subsequent phases. There follows a reset step 20 during which the value of the counter N_{R} counting the pulses of the stable reference REF is reset to zero, an end of counting phase indicator End flag is set to NO, and the value of the counter N₁ counting the pulses of the signal S1 output by the first oscillator OSC1 is reset to zero.

The value of the counter N_{R} is incremented in the step 21 when, after a latency time (step 22) corresponding to the period of the stable reference REF, it is observed, after comparison in the step 23, that the value of the counter N_{R} remains less than a predetermined value M. The value M thus corresponds to the number of pulses of the stable reference REF defining the duration of the counting phase. When the value of the counter N_{R} reaches the value M, the process for counting the pulses of the stable reference REF stops at the step 24 where the End flag is set to YES, which signals the end of the counting phase. When the counting phase ends at the step 24, the second oscillator OSC2 is reset to standby mode in the step 31 by generating a signal MV for setting the second oscillator OSC2 to standby mode.

While the steps 21, 22 and 23 described above are running, the value of the counter N₁ is incremented in the step 11, when, after a latency time (step 12) corresponding to the period of the signal S1, the fact that the counting phase is not finished is detected by examining the value of the End flag.

If, however, the value of the End flag indicates that the counting phase is finished, then, in the step 33, the value of division factor N intended to program the divider DIV1 is then determined as being the number N₁ of pulses of the low-consumption oscillator as counted, multiplied by the value of the frequency reference obtained by initial calibration F_{R} and divided by the number of cycles M of the frequency reference during which counting was enabled. A signal of frequency F′1 is therefore obtained at the output of the programmable divider, such that:
F′₁=F₁/N=(F₁/N₁)*(M/F_{R})

that is, a signal of frequency 1 Hz, therefore giving a second.

If, now, the instantaneous frequency F1 of the first oscillator OSC1 increases, that is, the number of pulses N₁ counted increases, the value of the division factor N applied to the divider DIV1 will be proportionally greater. After such a programming of the first divider DIV1 with said value, the time reference RTC output by the device is thus readjusted.

The predetermined number M of pulses for the stable reference REF is chosen so as to count, for example, approximately a million pulses on the first oscillator OSC1. This number of pulses must be adjusted according to the accuracy required for the time base: the higher the number, the greater the accuracy obtained, but the higher the average consumption of the device.

To reduce the consumption of the device according to the invention, only the oscillator OSC1 operating at the lowest frequency is permanently excited. According to an advantageous embodiment, the second oscillator OSC2 is intermittently set to standby mode. The stable reference REF is therefore available only in the operating mode in which the oscillator OSC2 is activated.

This provides for a significant reduction in the consumption of the device. With a frequency of the low-consumption oscillator around 1 MHz and a frequency difference of around 100 kHz, ten seconds of initial calibration are needed to obtain the stable frequency reference REF, but just one second is needed to achieve a count of a million cycles of the permanently-powered oscillator OSC1. The result is a time base with the second accurate to one ppm.

With the device according to the invention, it is the thermal inertia of the equipment in which it is fitted, for example a timepiece, which will determine the rate of reactivation of the high-frequency oscillator. Because of the high value of the thermal drift of a resonator (around 30 ppm/° C.), the readjustment of the division factor N needs to take place at at least each tenth of a degree in a temperature variation. With an inertia of around 1° C./min, it is therefore necessary to reactivate the higher frequency oscillator OSC2 every 6 s for a duration of 1 s, so reducing the consumption required to operate the system by a factor of 6, compared to a device in which both oscillators are operating permanently.

The production accuracy of the resonator gives an absolute frequency reference accurate to ±0.05%. A drift of 30 ppm/° C. over a temperature range of ±15° C. also produces a similar overall drift. If, therefore, a programmable divider DIV1 is used that is capable of generating a division factor of between 99.9% and 100.1% of the value of the frequency of the permanently-powered oscillator OSC1, the absolute accuracy and the thermal variations can be compensated in one go, without requiring any prior tuning of the resonators.

Moreover, because of the availability of a temperature-stable time reference REF and of a signal from the first oscillator OSC1 presenting a good linearity with temperature (if the effect of the second order thermal coefficient is disregarded), the value of the frequency of the permanently-connected first oscillator OSC1 becomes a direct indication of the temperature of the oscillators and this, with a good linearity, in digital form and accurate to around 1/30th of a ° C.

In this case, it is necessary to measure, in the calibration phase, the initial temperature T₀ and to count for this temperature the number of pulses N₁₀ of the first oscillator OSC1 during the predetermined number of pulses M. This counting procedure is the same as the counting phase described previously, used outside the calibration phase, in normal operating mode. These initial values T₀ and N₁₀ will be stored in the calibration block, like the reference frequency F_{R}, in a non-volatile manner. In normal operation, the temperature will then be re-estimated, after each counting phase, from the number of pulses N₁ of the signal S1 from the first oscillator, as a function of the number N₁ obtained and according to the formula:
T=T₀+(N₁−N₁₀)/(N₁₀*α₁)

Advantageously, the control block CTRL therefore includes means for determining the temperature difference ΔT=T−T₀ and generating, according to the step 35, represented by a broken line in FIG. 3, the value of this temperature difference according to the formula:
ΔT=(N₁−N₁₀)/(N₁₀*α₁).

These considerations result in a multitude of application variants of the invention which will either exploit this temperature information for itself by using it in a thermometer-type application, or simply exploit this information the better to regulate the duration of the standby/active phases of the oscillator OSC2 and therefore minimize the consumption of the device according to the invention.

Thus, according to the diagram in FIG. 3, the time interval elapsing between a switch to standby mode and the subsequent reactivation is determined by a latency time (step 32) of a value τᵥ which corresponds to a number of pulses of the signal S1 from the first oscillator OSC1. This value can be fixed and, in this case, determined according to the required accuracy on the time reference RTC and the maximum possible thermal drift. This value can also be determined after each counting phase, for example by a method of linear prediction on the frequency drift measured by the correction factor N or more directly, according to the example suggested in FIG. 3 by the step 40, from the value N₁ as counted following the step 13.

To conclude, the invention that has just been described can not only be used in implementing time bases, but also in any thermometer-type application requiring high accuracy.

1-12. (canceled)

13. A layout, delivering an output signal intended to form a time reference, including:
first oscillator, including a silicon resonator of frequency F₁ and of natural frequency F₁₀, generating an output signal, said resonator having a first order thermal coefficient α₁;
an oscillator circuit including a second oscillator, said second oscillator outputting a signal and including a silicon resonator of frequency F₂ different from that of said resonator of said first oscillator and of natural frequency F₂₀;
said resonator of said second oscillator presenting a first order thermal coefficient α₂ in a ratio λ.F₁₀/F₂₀ with said first order thermal coefficient α₁, λ being a proportionality factor, and said oscillator circuit also including a frequency divider dividing said frequency F₂ of said signal output of said second oscillator by said factor λ and generating an output signal of said oscillator circuit;
means for generating, by frequency difference between said signal output by said first oscillator and said signal output by said oscillator circuit, a first temperature-stable time reference;
means for determining a frequency drift due to the temperature of said signal output by said first oscillator by comparing the signal output with said first temperature-stable time reference; and
programmable correction means which, according to the value of said drift, divide the frequency of said signal output by said first oscillator and generate said layout output signal forming a second temperature-stable time reference.

14. The layout according to claim 13, further including:
means for counting, during a counting phase and over a predetermined number of cycles of said first time reference, a number of pulses generated by said first oscillator; and
means for determining said frequency drift and controlling said programmable correction means according to said number of pulses counted and said number of cycles of said first time reference during which counting was enabled.

15. The layout according to claim 14, further including:
means of selecting a standby mode for intermittently setting said second oscillator to the standby mode, wherein said counting phase runs during a phase of activity of said second oscillator.

16. The layout according to claim 15, wherein said means of selecting a standby mode includes means for varying the time interval between two successive phases of activity, according to the accuracy required for said second time reference and/or to said number of pulses counted for said first oscillator in at least one of the preceding counting phases.

17. The layout according to claim 14, further including means for generating temperature information from said number of pulses generated by said first oscillator in said counting phase.

18. The layout according to claim 15, further including means for generating temperature information from said number of pulses generated by said first oscillator in said counting phase.

19. The layout according to claim 16, further including means for generating temperature information from said number of pulses generated by said first oscillator in said counting phase.

20. The layout according to claim 13, further including means for storing calibration information concerning the first temperature-stable time reference.

21. The layout according to claim 14, further including means for storing calibration information concerning the first temperature-stable time reference.

22. The layout according to claim 17, further including means for storing calibration information concerning the first temperature-stable time reference

23. The layout according to claim 13, wherein said correction means includes a programmable frequency divider having a range of division factors with which to compensate the frequency drifts of said first oscillator due to the temperature and/or the absolute accuracy of the first oscillator.

24. The layout according to claim 17, wherein said correction means includes a programmable frequency divider having a range of division factors with which to compensate the frequency drifts of said first oscillator due to the temperature and/or the absolute accuracy of the first oscillator.

25. The layout according to claim 22, wherein said correction means includes a programmable frequency divider having a range of division factors with which to compensate the frequency drifts of said first oscillator due to the temperature and/or the absolute accuracy of the first oscillator.

26. A time base including a layout according to claim 13.

27. A thermometer including a layout according to claim 17.

28. A thermometer including a layout according to claim 22.

29. A thermometer including a layout according to claim 25.

30. A timepiece including a layout according to claim 13.

31. A timepiece including a layout according to claim 17.

32. A method of generating a signal intended to form a time reference including:
generating a first output signal of a first frequency F₁ by a first oscillator including a silicon resonator of natural frequency F₁₀ and of first order thermal coefficient α₁;
generating a signal of a second frequency F₂, different from said first frequency, by a second oscillator including a silicon resonator of natural frequency F₂₀ and which presents a first order thermal coefficient α₂ in a ratio λ.F₁₁/F₂₀ with said first order thermal coefficient α₁, λ being a proportionality factor;
dividing said second frequency F₂ of said signal output by said second oscillator by said factor λ, to generate a second output signal;
generating a first temperature-stable time reference by frequency difference between said first signal output by said first oscillator and said second output signal;
determining, by comparison of said signal output by said first oscillator with said first time reference, the frequency drift due to the temperature of said signal output by said first oscillator; and
correcting, according to the value of said drift, said frequency of said signal by said first oscillator to generate said signal forming a second time reference.
